(19) United States
(12) Patent Application Publication
(10) Pub. No.: US 2026/0163524 A1
(43) Pub. Date: Jun. 11, 2026

(54) COMPUTER SYSTEM AND METHOD FOR OPTIMIZING TEMPERATURE ADJUSTMENT MECHANISM OF RING OSCILLATOR

(71) Applicant: Nuvoton Technology Corporation, Hsinchu Science Park (TW)

(72) Inventor: Hen-Kai CHANG, Hsinchu City (TW)

(21) Appl. No.: 19/339,973

(22) Filed: Sep. 25, 2025

(30) Foreign Application Priority Data
Dec. 5, 2024 (TW) 113147202

(51) Int. Cl. H03B 5/04; G06F 1/20; G06F 1/3234; H03L 1/02

(52) U.S. Cl. CPC H03B 5/04; G06F 1/206; G06F 1/3234; H03L 1/026

(57) ABSTRACT

A computer system for optimizing a temperature adjustment mechanism of a ring oscillator (RC) is provided. The computer system includes a storage unit and a processing unit. The storage unit stores an RC characteristic data set. The RC characteristic data set includes one or more characteristics of each of a plurality of RCs and an optimal temperature coefficient set of the each RC. The characteristics of the each RC include a temperature-frequency relationship of the RC. The processing unit loads program instructions from the storage unit to receive one or more target characteristics of a target RC, and to determine a target temperature coefficient set of the target RC based on the RC characteristic data set and the target characteristics. The target characteristics include a temperature-frequency relationship of the target RC.

### CROSS REFERENCE TO RELATED APPLICATIONS

This application claims priority of Taiwan Patent Application No. 113147202, filed on Dec. 5, 2024, the entirety of which is incorporated by reference herein.

### TECHNICAL FIELD

The present disclosure relates to a temperature adjustment mechanism for a ring oscillator, and in particular it relates to a method for optimizing the temperature adjustment mechanism of the ring oscillator.

### BACKGROUND

A ring oscillator (RC) is a closed-loop circuit composed of an odd number of inverters. Signals can be transmitted back and forth between these inverters and continuously inverted, thereby forming the oscillation. Therefore, ring oscillators are often used as a source of clock signals for integrated circuits (IC) and microcontroller units (MCU).

Since the frequency of a ring oscillator will vary with temperature (this is known as “temperature drift”), when a ring oscillator is used as a clock signal source, the frequency variation with temperature of the RC should be controlled, and kept within an acceptable range (e.g., +2%) to provide the IC or MCU with a specific and stable clock signal.

Generally speaking, the frequency variation of the RC with temperature can be controlled by a temperature adjustment mechanism. This mechanism can be a combination of two temperature coefficients: a positive temperature coefficient (Positive trim, abbreviated P trim) and a negative temperature coefficient (Negative trim, abbreviated N trim). By adjusting the different values of the positive temperature coefficient (P value) and the negative temperature coefficient (N value), the changes in frequency with temperature in the RC can be determined. Among the various combinations of P values and N values, the (P, N) combination that exhibits the smallest change in frequency with temperature can be identified as the optimal temperature coefficient set, ensuring that the RC used as the clock signal source operates with the optimal temperature coefficient set. In other words, the optimal temperature coefficient set should be found for each RC to provide a clock signal at a specific frequency.

The current method for determining the optimal temperature coefficient set includes adjusting different positive temperature coefficient values (P values) and negative temperature coefficient values (N values). The method includes conducting temperature tests on the entire IC in a temperature chamber under different (P, N) combinations, and measuring and recording the frequency changes of the IC's RC with temperature. The method includes selecting the (P, N) combination with the smallest variation from among the many records as the optimal temperature coefficient set (P_{best}, N_{best}). When ICs are mass produced, however, it is impractical to measure the frequency changes of an RC under different (P, N) combinations for each IC.

Accordingly, there is a need for a computer system and method for optimizing the temperature adjustment mechanism of a ring oscillator to overcome the foregoing issues.

### BRIEF SUMMARY

The present disclosure provides a computer system for optimizing a temperature adjustment mechanism of a ring oscillator (RC). The computer system includes a storage unit and a processing unit. The storage unit stores an RC characteristic data set. The RC characteristic data set includes one or more characteristics of each of a plurality of RCs and an optimal temperature coefficient set of the each RC. The characteristics of the each RC include a temperature-frequency relationship of the RC. The processing unit loads program instructions from the storage unit to receive one or more target characteristics of a target RC, and to determine a target temperature coefficient set of the target RC based on the RC characteristic data set and the target characteristics. The target characteristics include a temperature-frequency relationship of the target RC.

The present disclosure provides a method for optimizing a temperature adjustment mechanism of a ring oscillator (RC), executed by a computer system. The method includes receiving one or more target characteristics of a target RC and determining a target temperature coefficient set of the target RC based on an RC characteristics data set and the target characteristics. The target characteristics include a temperature-frequency relationship of the target RC. The RC characteristics data set includes one or more characteristics of each of a plurality of RCs and an optimal temperature coefficient set of the each RC. The characteristics of the each RC include a temperature-frequency relationship of the RC.

The computer system and method disclosed herein for optimizing the temperature adjustment mechanism of a ring oscillator (RC) can identify the optimal temperature coefficient set for the target RC based on a limited amount of data from the RC characteristic data set. Furthermore, compared to the traditional approach of measuring all possible temperature coefficient sets for the target RC to identify the optimal temperature coefficient set, the embodiments of the present disclosure can more efficiently identify the optimal temperature coefficient set for the target RC through data comparison or machine learning. This enables the target RC to achieve optimal temperature drift performance in output frequency and thereby enhancing the stability of IC operation.

### BRIEF DESCRIPTION OF THE DRAWINGS

The present disclosure can be better understood by referring to the accompanying drawings in conjunction with the description of the exemplary embodiments. Furthermore, it should be understood that the order of execution of each block may be changed, and/or certain blocks may be changed, omitted, or combined in the flowcharts of the present disclosure.

FIG. 1 is a system architecture diagram of a computer system according to an embodiment of the present disclosure. The processing unit of the computer system executes a method for optimizing a temperature adjustment mechanism for a ring oscillator.

FIG. 2 is a data flow diagram illustrating the steps for determining the target temperature coefficient set for the target RC according to an embodiment of the present disclosure.

FIG. 3 is a data flow diagram illustrating the steps for determining the target temperature coefficient set for the target RC according to an embodiment of the present disclosure.

FIG. 4 is a data flow diagram illustrating the steps for determining the target temperature coefficient set for the target RC according to an embodiment of the present disclosure.

### DETAILED DESCRIPTION

The following descriptions list various embodiments of the present disclosure, but are not intended to limit the scope of the disclosure. The actual scope of the disclosure is defined by the scope of the claims.

In the following embodiments, the same reference numerals represent the same or similar elements or components.

The serial numbers used in the specification and in the claims, such as “first”, “second”, etc., are for convenience only and do not indicate any order of precedence.

The description of embodiments of the device or system in the specification also applies to embodiments of the method, and vice versa.

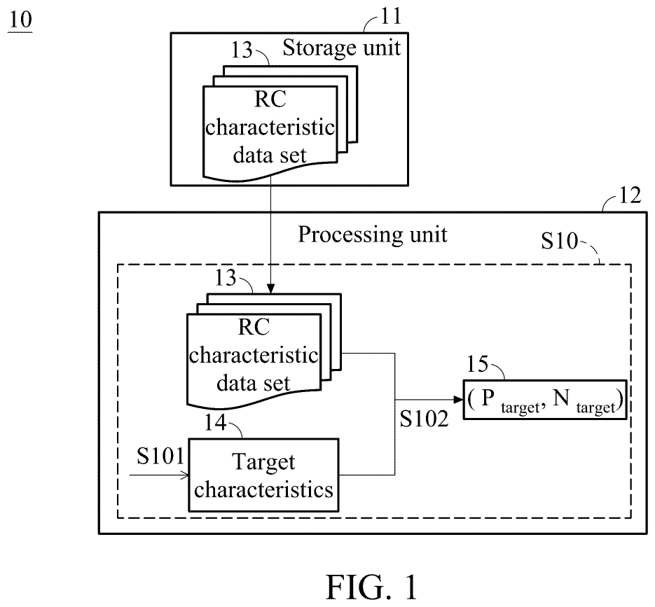

FIG. 1 is a system architecture diagram of a computer system 10 for optimizing the temperature adjustment mechanism of a ring oscillator according to an embodiment of the present disclosure. As shown in FIG. 1, the computer system 10 includes a storage unit 11 and a processing unit 12.

The computer system 10 may be any type of computer system or processing device capable of performing computations, such as a personal computer (e.g., a desktop computer or laptop), a server computer, or a mobile device (e.g., a tablet computer or smartphone), but the disclosure is not limited thereto.

The storage unit 11 may include a hard disk drive (HDD), a solid-state drive (SSD), an optical disc, or any type of device containing a non-volatile memory (e.g., read-only memory (ROM), electrically-erasable programmable read-only memory (EEPROM), flash memory, non-volatile random access memory (NVRAM)), but the disclosure is not limited thereto.

The processing unit 12 may include one or more general-purpose or specialized processors and combinations thereof for executing program instructions, such as a central processing unit (CPU) and/or a graphics processing unit (GPU). The processing unit 12 may further include a volatile memory, such as a dynamic random access memory (DRAM) and/or a static random access memory (SRAM), but the disclosure is not limited thereto.

As shown in FIG. 1, the storage unit 11 stores an RC characteristic data set 13. The RC characteristic data set 13 may include one or more characteristics of each of a plurality of RCs and an optimal temperature coefficient set corresponding to each RC. The characteristics of each RC may also include its temperature-frequency relationship.

The following provides Table 1 as an example of an RC characteristic data set. As shown in Table 1, the RC characteristic data set 13 may include at least three interrelated data fields: RC identifier, characteristics, and optimal temperature coefficient set (P_{best}, N_{best}). The characteristics may include at least the temperature-frequency relationship corresponding to the RC (i.e., the change in frequency with respect to temperature for the RC). Each row in Table 1 represents a single data entry in the RC characteristic data set 13. In this example, the RC characteristic data set 13 records K data entries (but the disclosure does not limit the number of data entries in the RC characteristic data set 13). Each data entry represents the temperature-frequency relationship and optimal temperature coefficient set (P_{best}, N_{best}) corresponding to each RC. For example, RC1 has the temperature-frequency relationship 1 and optimal temperature coefficient set (0, 0), RC2 has the temperature-frequency relationship 2 and optimal temperature coefficient set (3,0), and so on. Each RC has the best temperature drift performance (i.e., minimum temperature drift) under its optimal temperature coefficient set (P_{best}, N_{best}).

TABLE 1

| RC | Characteristics | (P_{best}, N_{best}) |
|---|---|---|
| 1 | temperature-frequency | (0, 0) |
| | relationship 1 | |
| 2 | temperature-frequency | (3, 0) |
| | relationship 2 | |
| . . . | . . . | . . . |
| K | temperature-frequency | (0, 1) |
| | relationship K | |

In one embodiment, the optimal temperature coefficient set (P_{best}, N_{best}) for each RC can be obtained by adjusting the temperature coefficient set (P, N) to measure multiple temperature-frequency relationships and selecting the temperature-frequency relationship with the smallest temperature drift. The temperature-frequency relationship refers to how the frequency of the corresponding RC varies with temperature, which can be represented by a linear function, a nonlinear function, a statistical chart, or a mapping table. Additionally, the aforementioned temperature chamber can be used to heat the IC to obtain the corresponding frequency of each RC at different temperatures, thereby obtaining the temperature-frequency relationship. However, the disclosure does not limit the specific data collection methods for the RC characteristic data set.

As shown in FIG. 1, the processing unit 12 executes a method S10 for optimizing the temperature adjustment mechanism of the ring oscillator. The method S10 may include steps S101 and S102.

In step S101, processing unit 12 receives one or more target characteristics 14 of a target RC. As described earlier, the target characteristics 14 include at least the temperature-frequency relationship of the target RC.

In step S102, a target temperature coefficient set 15 is determined by the processing unit 12 for the target RC based on the RC characteristic data set 13 and the target characteristics 14. The target temperature coefficient set 15 is represented as (P_{target}, N_{target}) in FIG. 1. The RC characteristic data set 13 can be loaded from the storage unit 11 into the random access memory of the processing unit 12 to execute the step S102.

In one embodiment of the present disclosure, the temperature-frequency relationship of the target RC can be obtained by adjusting the temperature of the target RC and recording the corresponding frequency of the target RC at multiple temperatures. For example, the implementation of temperature adjustment may involve the use of cold/hot plates, temperature chambers, infrared heaters, laser heaters, or other similar tools, but the disclosure is not limited thereto. The temperature of the target RC may be determined using a temperature sensor within the target IC, but the disclosure is not limited thereto.

In one embodiment of the present disclosure, the temperature of the target RC can be adjusted, without changing its ambient temperature, by adjusting electrical parameters of the target IC in which the target RC is located, such as voltage or current. In one implementation, the voltage and/or current generated during operation of the target IC can be adjusted according to a formula compliant with an industry standard, thereby adjusting the temperature of the target RC through the influence of the target IC's power consumption and package heat dissipation. The aforementioned formula is as follows:

$$Temperature rise = Voltage \times Current \times Package Temperature Coefficient$$

It should be noted that the target characteristics 14 and the characteristics in the RC characteristic data set 13 should use the same consistent representation method, such as the linear function, nonlinear function, statistical chart, or mapping table.

In one embodiment of the present disclosure, in addition to the temperature-frequency relationship, the characteristics in the RC characteristic data set 13 further include the temperature-power consumption relationship. Correspondingly, in addition to the temperature-frequency relationship of the target RC, the target characteristics 14 further include the temperature-power consumption relationship of the target RC. Table 2 below provides an example of the RC characteristic data set in this embodiment.

TABLE 2

| RC | Characteristic 1 | Characteristic 2 | (P_{best}, N_{best}) |
|---|---|---|---|
| 1 | temperature-frequency | temperature-power | (0, 0) |
| | relationship 1 | consumption | |
| | | relationship 1 | |
| 2 | temperature-frequency | temperature-power | (1, 0) |
| | relationship 2 | consumption | |
| | | relationship 2 | |
| . . . | . . . | . . . | . . . |
| K | temperature-frequency | temperature-power | (0, 3) |
| | relationship K | consumption | |
| | | relationship K | |

In this example, the RC characteristic data set 13 records K data entries (but the disclosure does not limit the number of data entries in the RC characteristic data set 13). Each data entry represents the temperature-frequency relationship, temperature-power consumption relationship, and optimal temperature coefficient set (P_{best}, N_{best}) corresponding to each RC. For example, RC1 has the temperature-frequency relationship 1, temperature-power consumption relationship 1, and optimal temperature coefficient set (0, 0), RC2 has the temperature-frequency relationship 2, temperature-power consumption relationship 2, and optimal temperature coefficient set (1, 0), and so on. Each RC has the best temperature drift performance in its temperature-frequency relationship and temperature-power consumption relationship under its optimal temperature coefficient set (P_{best}, N_{best}).

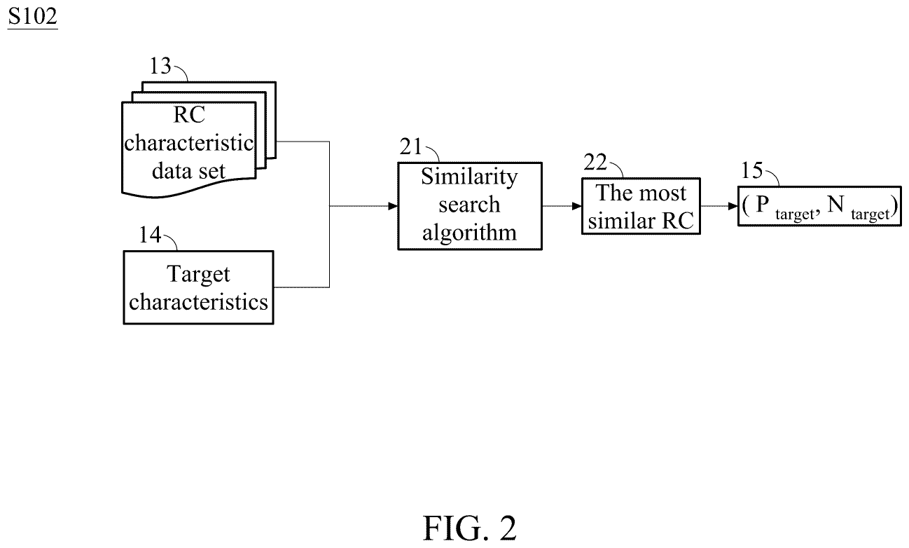

FIG. 2 is a data flow diagram illustrating the implementation of step S102 shown in FIG. 1 according to an embodiment of the present disclosure. In this embodiment, the step S102 may involve using a similarity search algorithm based on target characteristics 14 to select the most similar RC 22 from the RC characteristic data set 13. Subsequently, the optimal temperature coefficient set of the most similar RC 22 is obtained as the target temperature coefficient set 15.

In one embodiment, the similarity search algorithm 21 may involve calculating the similarity between the characteristics of each RC in the RC characteristic data set 13 and the target characteristics 14, and selecting the one with the highest similarity to obtain the most similar RC and the corresponding optimal temperature coefficient set. The similarity can be assessed using Euclidean distance, Manhattan distance, cosine similarity, or other metrics, but the disclosure is not limited thereto.

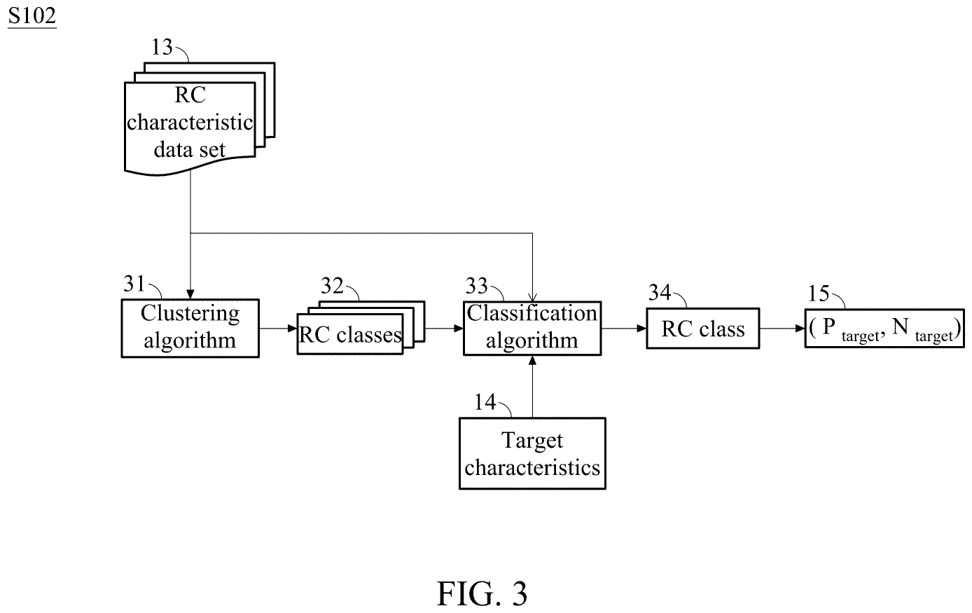

FIG. 3 is a data flow diagram illustrating the implementation of step S102 shown in FIG. 1 according to an embodiment of the present disclosure. In this embodiment, the step S102 may involve using a clustering algorithm 31 to determine multiple RC classes 32 of the RC characteristic data set 13, as well as the optimal temperature coefficient sets corresponding to the RC classes 32. Next, based on the target characteristics 14, a classification algorithm 33 is used to determine which of the RC classes 32 the target RC belongs to, and the optimal temperature coefficient set corresponding to the RC class to which it belongs is obtained as the target temperature coefficient set.

In one embodiment, after applying the clustering algorithm, the RC characteristic data set 13 may further include two data fields: an RC class and an optimal temperature coefficient set (P_{class}, N_{class}). As shown in Table 3, the RC characteristic data set 13 records K temperature-frequency relationships and optimal temperature coefficient sets (P_{best}, N_{best}) corresponding to each RC, as well as M RC classes and optimal temperature coefficient sets (P_{class}, N_{class}) corresponding to each R, where K>M. The optimal temperature coefficient set (P_{class}, N_{class}) corresponding to the RC class to which the target RC belongs will be used as the target temperature coefficient set 15. For example, if the classification algorithm determines that the target RC belongs to RC class 1, then the optimal temperature coefficient set (0,0) corresponding to RC class 1 will be used as the target temperature coefficient set 15; if the classification algorithm determines that the target RC belongs to RC class 2, then the optimal temperature coefficient set (2,0) corresponding to RC class 2 will be used as the target temperature coefficient set 15; and so on.

TABLE 3

| RC | Characteristic 1 | (P_{best}, N_{best}) | RC class | (P_{class}, N_{class}) |
|---|---|---|---|---|
| 1 | temperature- | (0, 0) | 1 | (0, 0) |
| | frequency | | | |
| | relationship 1 | | | |
| 2 | temperature- | (2, 0) | 2 | (2, 0) |
| | frequency | | | |
| | relationship 2 | | | |
| 3 | temperature- | (0, 1) | 1 | (0, 0) |
| | frequency | | | |
| | relationship 3 | | | |
| . . . | . . . | . . . | . . . | . . . |
| K | temperature- | (0, 2) | M | (0, 3) |
| | frequency | | | |
| | relationship K | | | |

In one embodiment, the clustering algorithm 31 may be, for example, the K-means algorithm, the Density-Based Spatial Clustering of Applications with Noise (DBSCAN) algorithm, or spectral clustering, but the disclosure is not limited thereto.

In one embodiment, the classification algorithm 33 may be a machine learning classification model established using the characteristic 1 and the RC class in Table 3, such as the nearest centroid classifier (also known as Rocchio classifier), k-Nearest Neighbors (k-NN), Decision Tree, Support Vector Machine (SVM), or Neural Network (NN) classification model, but the disclosure is not limited thereto.

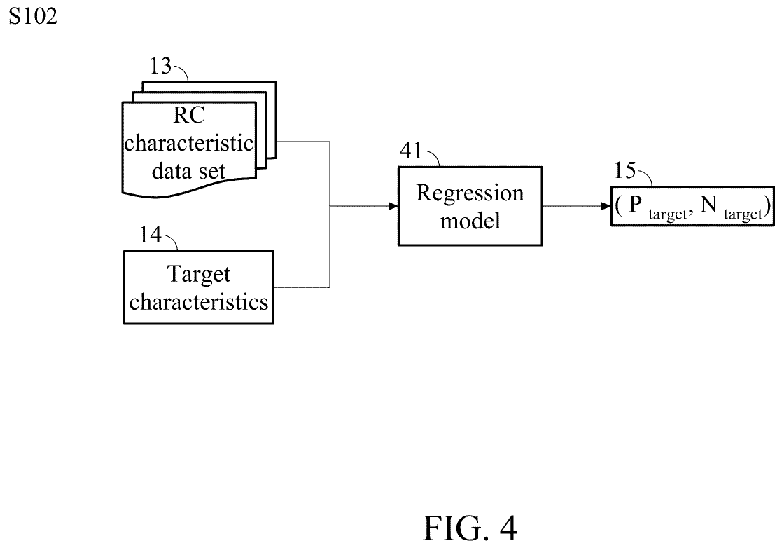

FIG. 4 is a data flow diagram illustrating the implementation of step S102 shown in FIG. 1 according to an embodiment of the present disclosure. In this embodiment, the step S102 may involve establishing a regression model 41 based on the RC characteristic data set 13. Next, the target characteristics 14 are input into the regression model 41, and the target temperature coefficient set 15 is directly obtained from the output of the regression model.

Specifically, the regression model 41 can be a machine learning regression model established based on the characteristics of each RC in the RC characteristic data set 13 and the corresponding optimal temperature coefficient set (P_{best}, N_{best}), such as the Linear Regression, Decision Tree Regression, Support Vector Regression (SVR), or neural network regression model, but the disclosure is not limited thereto.

The computer system and method disclosed herein for optimizing the temperature adjustment mechanism of a ring oscillator (RC) can identify the optimal temperature coefficient set for the target RC based on a limited amount of data from the RC characteristic data set. Furthermore, compared to the traditional approach of measuring all possible temperature coefficient sets for the target RC to identify the optimal temperature coefficient set, the embodiments of this disclosure can more efficiently identify the optimal temperature coefficient set for the target RC through data comparison or machine learning, enabling the target RC to achieve optimal temperature drift performance in output frequency and thereby enhancing the stability of IC operation.

The above paragraphs describe various embodiments. Clearly, the teachings of this specification can be implemented in various ways, and any specific architecture or function disclosed in the examples is only representative. Based on the teachings of this specification, those skilled in the art will understand that each embodiment disclosed herein can be implemented independently, or two or more embodiments can be implemented in combination.

Although the present disclosure has been described above with reference to embodiments, it is not intended to limit the present disclosure. Any person skilled in the art may make minor modifications and improvements without departing from the spirit and scope of the present disclosure. Therefore, the scope of protection of the disclosure shall be determined by the appended claims.

What is claimed is:

1. A computer system for optimizing a temperature adjustment mechanism of a ring oscillator (RC), comprising:
a storage unit, storing an RC characteristic data set, wherein the RC characteristic data set comprises one or more characteristics of each of a plurality of RCs and an optimal temperature coefficient set of the each RC, and wherein the characteristics of the each RC comprise a temperature-frequency relationship of the RC; and
a processing unit, loading program instructions from the storage unit, and configured to execute the program instructions to:
receive one or more target characteristics of a target RC, wherein the target characteristics comprise a temperature-frequency relationship of the target RC; and
determine a target temperature coefficient set of the target RC based on the RC characteristic data set and the target characteristics.

2. The computer system as claimed in claim 1, wherein the temperature-frequency relationship of the target RC is obtained by performing a temperature adjustment on the target RC and recording corresponding frequency of the target RC at multiple temperatures.

3. The computer system as claimed in claim 2, wherein the processing unit is further configured to adjust an electrical parameter of a target integrated circuit in which the target RC is located, to perform the temperature adjustment on the target RC.

4. The computer system as claimed in claim 1, wherein the characteristics of the each RC in the RC characteristic data set further comprise a temperature-power consumption relationship; and
wherein the target characteristics of the target RC further comprise the temperature-power consumption relationship of the target RC.

5. The computer system as claimed in claim 1, wherein the processing unit is further configured, based on the target characteristics, to apply a similarity search algorithm to select a most similar RC from the RC characteristic data set and obtain the optimal temperature coefficient set of the most similar RC as the target temperature coefficient set.

6. The computer system as claimed in claim 1, wherein the processing unit is further configured to apply a clustering algorithm to determine multiple RC classes for the plurality of RCs of the RC characteristic data set and multiple optimal temperature coefficient sets corresponding to the multiple RC classes; and
wherein the processing unit is further configured, based on the target characteristics, to apply a classification algorithm to determine which of the RC classes the target RC belongs to, and to obtain the optimal temperature coefficient set corresponding to the RC class as the target temperature coefficient set.

7. The computer system as claimed in claim 1, wherein the processing unit is further configured to establish a regression model based on the RC characteristic data set; and
wherein the processing unit is further configured to input the target characteristics into the regression model and obtain the target temperature coefficient set output by the regression model.

8. A method for optimizing a temperature adjustment mechanism of a ring oscillator (RC), executed by a computer system, comprising:
receiving one or more target characteristics of a target RC, wherein the target characteristics comprise a temperature-frequency relationship of the target RC; and
determining a target temperature coefficient set of the target RC based on an RC characteristic data set and the target characteristics;
wherein the RC characteristic data set comprises one or more characteristics of each of a plurality of RCs and an optimal temperature coefficient set of the each RC, and wherein the characteristics of the each RC comprise a temperature-frequency relationship of the RC.

9. The method as claimed in claim 8, wherein the temperature-frequency relationship of the target RC is obtained by performing a temperature adjustment on the target RC and recording corresponding frequency of the target RC at multiple temperatures.

10. The method as claimed in claim 9, wherein the temperature adjustment is performed on the target RC by adjusting an electrical parameter of a target integrated circuit in which the target RC is located.

11. The method as claimed in claim 8, wherein the characteristics of the each RC in the RC characteristic data set further comprise a temperature-power consumption relationship; and
wherein the target characteristics of the target RC further comprise a temperature-power consumption relationship of the target RC.

12. The method as claimed in claim 8, wherein determining the target temperature coefficient set of the target RC based on the RC characteristic data set and the target characteristics further comprises:
applying a similarity search algorithm to select a most similar RC from the RC characteristic data set based on the target characteristics and obtain the optimal temperature coefficient set of the most similar RC as the target temperature coefficient set.

13. The method as claimed in claim 8, further comprising:
applying a clustering algorithm to determine multiple RC classes for the plurality of RCs of the RC characteristic data set and multiple optimal temperature coefficient sets corresponding to the multiple RC classes;
wherein determining the target temperature coefficient set of the target RC based on the RC characteristic data set and the target characteristics further comprises:
applying a classification algorithm to determine, based on the target characteristics, which of the RC classes the target RC belongs to, and to obtain the optimal temperature coefficient set corresponding to the RC class as the target temperature coefficient set.

14. The method as claimed in claim 8, wherein determining the target temperature coefficient set of the target RC based on the RC characteristic data set and the target characteristics further comprises:
establishing a regression model based on the RC characteristic data set; and
inputting the target characteristics into the regression model and obtaining the target temperature coefficient set output by the regression model.
